(19) United States
(12) Patent Application Publication
(10) Pub. No.: US 2009/0174457 A1
(43) Pub. Date: Jul. 9, 2009

(54) IMPLEMENTING LOW POWER LEVEL SHIFTER FOR HIGH PERFORMANCE INTEGRATED CIRCUITS

(76) Inventors: Derick Gardner Behrends, Rochester, MN (US); Todd Alan Christensen, Rochester, MN (US); Travis Reynold Hebig, Rochester, MN (US)

Correspondence Address: IBM CORPORATION;ROCHESTER IP LAW DEPT 917, 3605 HIGHWAY 52 N, ROCHESTER, MN, 55901-7829, US

(21) Appl. No.: 11/970,624

(22) Filed: Jan. 8, 2008

(51) Int. Cl. H03L 5/00

(52) U.S. Cl. 327/333

(57) ABSTRACT

A low power level shifter circuit for high performance integrated circuits includes an input inverter operating in a domain of a first voltage supply and receiving an input signal and a design structure on which the subject circuit resides is provided. An output stage operating in a domain of a higher second voltage supply includes a first output inverter connected to the input inverter and a second output inverter connected in series with the first output inverter. The second output inverter provides a level shifted output signal having a voltage level corresponding to the second voltage supply. A series connected finisher transistor and finisher control transistor are connected between the second voltage supply and an input to the first output inverter. The finisher control transistor is activated responsive to the input signal. A path control transistor controls a path between the first voltage supply and the input inverter. The path control transistor being activated responsive to the level shifted output signal.

### FIELD OF THE INVENTION

The present invention relates generally to the data processing field, and more particularly, relates to a low power level shifter circuit and a method for implementing low power level shifter circuits for high performance integrated circuits, and a design structure on which the subject circuit resides.

### DESCRIPTION OF THE RELATED ART

As technology advances, scaling of the power supply voltage occurs for power reduction and reliability reasons. Certain types of circuits are more sensitive to this reduction in voltage such as analog, memory and input/output (I/O) circuits. To combat this, many chip designs have added extra power supply domains to use in these sensitive circuits.

Level shifter circuits are utilized in integrated circuits for changing the voltage of a signal from a first voltage to a second voltage, such as from a high to a low operating voltage, or from a low to a high operating voltage.

Referring to FIGS. 1A, and 1B, there is shown a prior art circuit 100 including a first power supply voltage VDDA and a second higher power supply voltage VDDB. Circuit 100 includes a pair of inverters with an input inverter receiving an input signal and providing an output OUTPUT_B. The input inverter is defined by a series connected P-channel field effect transistor (PFET) 102 and an N-channel field effect transistor (NFET) 104 connected between the first power supply voltage VDDA and ground. An output inverter is defined by a series connected PFET 106 and NFET 108 connected between the second power supply voltage VDDB and ground. The input inverter output OUTPUT_B is applied to the output inverter that provides an output signal OUTPUT.

As shown in FIGS. 1A, and 1B when static logic gates are connected normally at the interface between a lower VDDA and a higher VDDB, problems can result. For example, as illustrated in FIG. 1B as VDDB rises greater than a PFET threshold voltage above VDDA, the output inverter PFET 106 will turn on and DC current will flow through the output inverter gate connected to VDDB.

This prevents a good zero level on the output node, as indicated by the label>0 at the OUTPUT in FIG. 1B.

Referring to FIG. 2, the problem can be exacerbated with wider gates in which multiple PFETs could be turned on and leak DC current. FIG. 2 illustrates a prior art two-input NAND gate 200 including a pair of input inverters, defined by PFET 202 and NFET 204, and PFET 206 and NFET 208, receiving INPUT1 and INPUT 2 and connected between the first power supply voltage VDDA and ground. NAND gate 200 includes PFET 210, NFET 212, and PFET 216, NFET 218 having a respective gate input connected to the respective common connection of PFET 202 and NFET 204, and PFET 206 and NFET 208 and providing output OUTPUT B and operating in the domain of the second power supply voltage VDDB. OUTPUT B is applied to the output inverter defined by PFET 220, NFET 222 that provides an output signal OUTPUT. When VDDB rises greater than a PFET threshold voltage above VDDA, each of the PFETs 210, 216, and NFET 222 can turn on leaking DC current.

FIG. 3 illustrates a prior art level shifter circuit 300. Level shifter circuit 300 includes an input inverter 302 connected to a first voltage supply domain VDD1 receiving an input signal IN. Level shifter circuit 300 includes a pair of cross-coupled PFETs 304, 306 respectively connected between a second voltage supply domain VDD2 and a respective NFET 308, 310. In operation with an input signal IN of logical 1, NFET 308 is turned on and input inverter 302 provides a logical 0, NFET 310 is turned off. PFET 306 is turned on driving the output OUT to VDD2 and PFET 304 turned off. With an input signal IN of logical 0, NFET 308 is turned off and input inverter 302 provides a logical 1, NFET 310 is turned on, driving the output OUT to logical 0 and PFET 304 turned on. The gate input to PFET 306 approaches VDD2 and PFET 306 is turned off.

Problems with many known level shifter circuits include degraded power and performance characteristics. For example, in the prior art level shifter circuit 300 shoot through current can result on both transitions from low to high and from high to low. Also prior art level shifter circuit 300 fails to enable high frequency operation that may be required for some particular applications.

FIG. 4 shows a low power level shifter circuit 400 invented by the same inventors having many advantages over the prior art shown in FIG. 3 including reduced fan-in, limiting shoot-through current to one transition, and reducing overall delay to enable faster operation. Level shifter circuit 400 includes a PFET 402 and NFET 404 receiving an input signal INPUT. PFET 402 is connected between a first power supply voltage VDDA and a PFET 406 connected in series with NFET 404. Level shifter circuit 400 includes a pair of series connected inverters operating in a domain of a second power supply voltage VCS, having an input connected to the drain source connection of PFET 406 and NFET 404 and providing an output OUTPUT of level shifter circuit 400. The pair of series connected inverters are defined by PFET 408, NFET 410, PFET 412 and NFET 414 connected between the second power supply voltage VCS and ground. PFET 406 has a gate connected to the output OUTPUT of level shifter circuit 400. A PFET 416 connected between the second power supply voltage VCS and the input to the first inverter defined by PFET 408, NFET 410 has a gate connected to an output of the first inverter and input to the second inverter defined by PFET 412, NFET 414. A disadvantage to the low power level shifter circuit shown in FIG. 4 is that it is very sensitive to the ratio of device strengths PFET 416 and NFET 404. This ratio must be kept small. This constraint can limit the performance of the circuit.

A need exists for an effective mechanism for implementing low power level shifter circuits for high performance integrated circuits.

### SUMMARY OF THE INVENTION

Principal aspects of the present invention are to provide a low power level shifter circuit and a method for implementing low power level shifter circuits for high performance integrated circuits. Other important aspects of the present invention are to provide such low power level shifter circuit and a method for implementing low power level shifter circuits for high performance integrated circuits substantially without negative effect and that overcome many of the disadvantages of prior art arrangements.

In brief, a low power level shifter circuit and a method implementing low power level shifter circuits for high performance integrated circuits and a design structure on which the subject circuit resides are provided. An input inverter operates in a domain of a first voltage supply. The input inverter receives an input signal and provides a first inverted signal output. An output stage operating in a domain of a second voltage supply higher than the first voltage supply includes a first output inverter connected to the input inverter and a second output inverter connected in series with the first output inverter. The second output inverter provides a level shifted output signal having a voltage level corresponding to the second voltage supply. A series connected finisher transistor and finisher control transistor are connected between the second voltage supply and an input to the first output inverter. The finisher control transistor is activated responsive to the input signal. A path control transistor controls a path between the first voltage supply and the input inverter. The path control transistor being activated responsive to the level shifted output signal.

In accordance with features of the invention, the level shifter circuit enables enhanced power and performance characteristics. The level shifter circuits reduce overall delay, increase level shifting functionality, and enable more flexibility in device sizing for circuit performance.

### BRIEF DESCRIPTION OF THE DRAWINGS

The present invention together with the above and other objects and advantages may best be understood from the following detailed description of the preferred embodiments of the invention illustrated in the drawings, wherein:

FIGS. 1A and 1B illustrate a prior art circuit including a first power supply voltage VDDA and a second higher power supply voltage VDDB;

FIG. 2 illustrates a prior art NAND gate including a first power supply voltage VDDA and a second higher power supply voltage VDDB;

FIG. 3 illustrates a prior art level shifter circuit;

FIG. 4 illustrates another prior art level shifter circuit;

FIGS. 5, and 6 are schematic diagrams illustrating an exemplary level shifter circuits in accordance with the preferred embodiment; and

FIG. 7 is a flow diagram of a design process used in semiconductor design, manufacturing, and/or test.

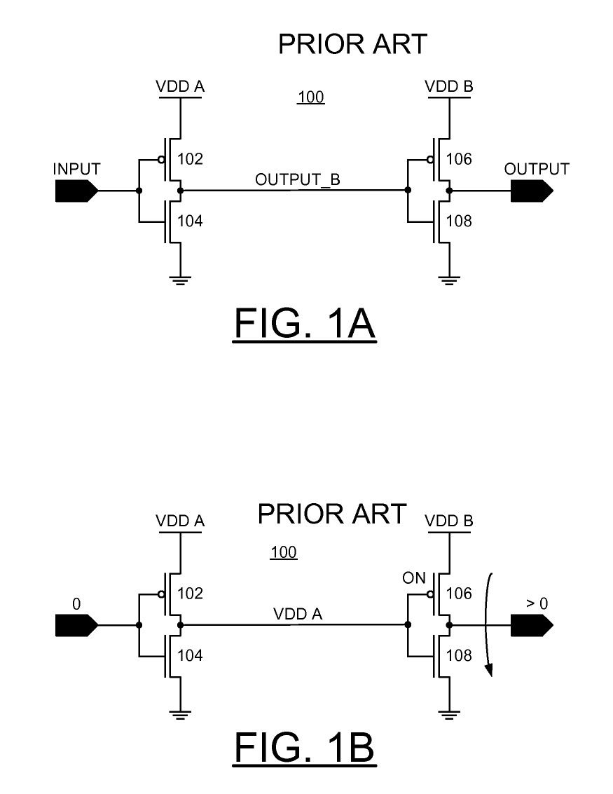

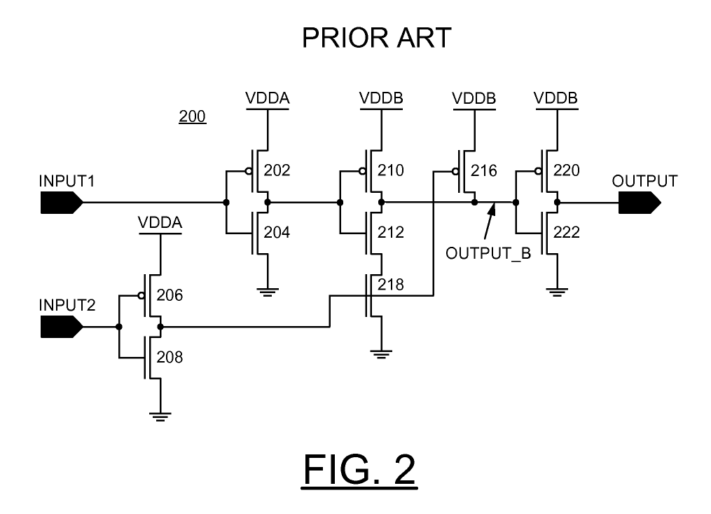

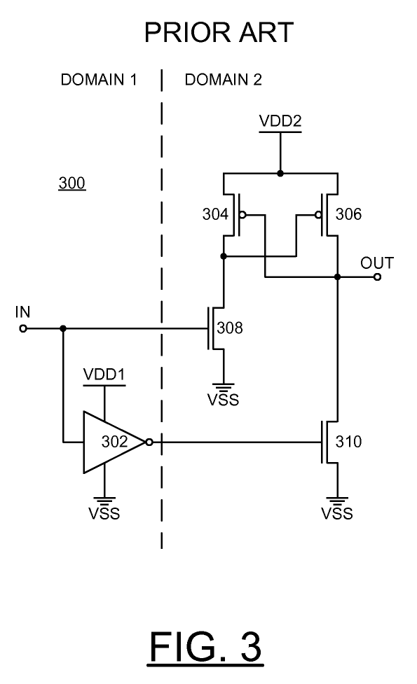

### DETAILED DESCRIPTION OF THE PREFERRED EMBODIMENTS

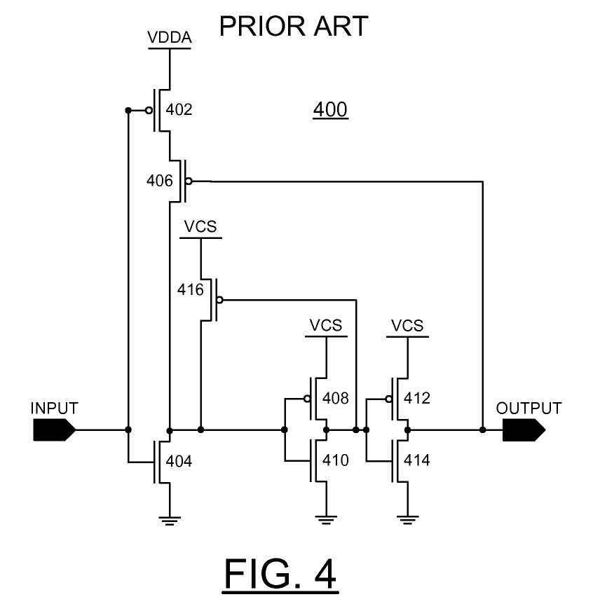

In accordance with features of the invention, level shifter circuits are provided having excellent power and performance characteristics, providing improved performance characteristics over known level shifter circuits, such as shown in FIG. 4. The novel level shifter circuits reduce overall delay, increase level shifting functionality, have slightly better input noise immunity for “rising above ground” noise, and enable more flexibility in device sizing for circuit performance. This method for implementing the level shifter circuits advantageously is applied to various static logic circuits.

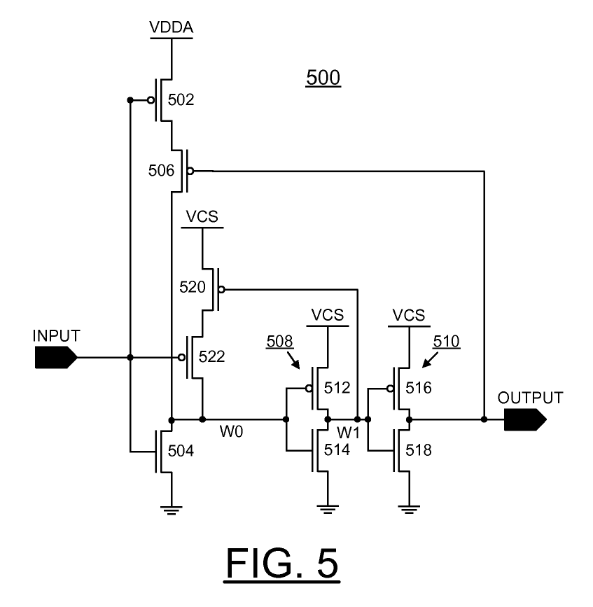

Having reference now to the drawings, in FIG. 5, there is shown an exemplary level shifter circuit generally designated by the reference character 500 in accordance with the preferred embodiment. Level shifter circuit 500 includes an input stage P-channel field effect transistor (PFET) 502 and an N-channel field effect transistor (NFET) 504 receiving an input signal INPUT. PFET 502 is connected between a first power supply voltage VDDA and a path control PFET 506 connected in series with the pull down NFET 504.

Level shifter circuit 500 includes an output stage pair of series connected inverters 508, 510 operating in a domain of a second power supply voltage VCS, the inverter 510 providing an output OUTPUT of level shifter circuit 500 having a voltage level corresponding to the second voltage supply VCS and a logic value corresponding to the inverse of the input signal INPUT. The series connected input stage path control PFET 506 has a gate connected to the output OUTPUT of level shifter circuit 500.

The pair of series connected inverters 508, 510 are defined by a series connected PFET 512 and NFET 514, and a series connected PFET 516 and NFET 518 respectively connected between the second power supply voltage VCS and ground. The drain source connection of PFET 506 and NFET 504 at node W0 is connected to an input of the first inverter 508 defined by a series connected PFET 512 and NFET 514.

A pair of series connected PFETs 520, 522 is connected between the second power supply voltage VCS and the input to the first inverter 508. The PFET 520 is a finisher PFET having a gate connected to a node W1 at an output of the first inverter 508 and input to the second inverter 510 defined by PFET 512, NFET 514. The PFET 522 is a finisher control PFET having a gate connected to the input signal INPUT.

In operation of the level shifter circuit 500, when the input signal INPUT falls, then the pull down NFET 504 is turned off, and PFET 502 is turned on, pulling node W0 high. The finisher control PFET 522 is turned on. The output of inverter 508 pulls node W1 low and the output of the second inverter 510 pulls OUTPUT high. The OUTPUT rises to the second voltage level VCS and the path control PFET 506 is turned off so that the input stage path from the first voltage level VDDA is cut off. The output of first inverter 508 at node W1 is low, so the finisher PFET 520 is turned on causing the rise of node W0 to the second voltage level VCS.

In operation of the level shifter circuit 500, when the input signal INPUT rises, the pull down NFET 504 is turned on, the PFET 522 is turned off. With the PFET 522 off, the finisher PFET 520 is turned off. As a result the pull down NFET 504 does not need to overcome a conducting finisher device, as required in prior art arrangements, such as shown in FIG. 4. In known 45-nanometer technology, this results in up to a 20% improvement in overall delay and up to a 200 mV improvement in level shifting functionality. This configuration also removes the circuit sensitivity to the ratio of the device strengths of the finisher PFET 520 and pull down NFET 504. Removing this design constraint allows the circuit to be tuned for custom circuit performance including pulse widths, propagation delay, and slew rates.

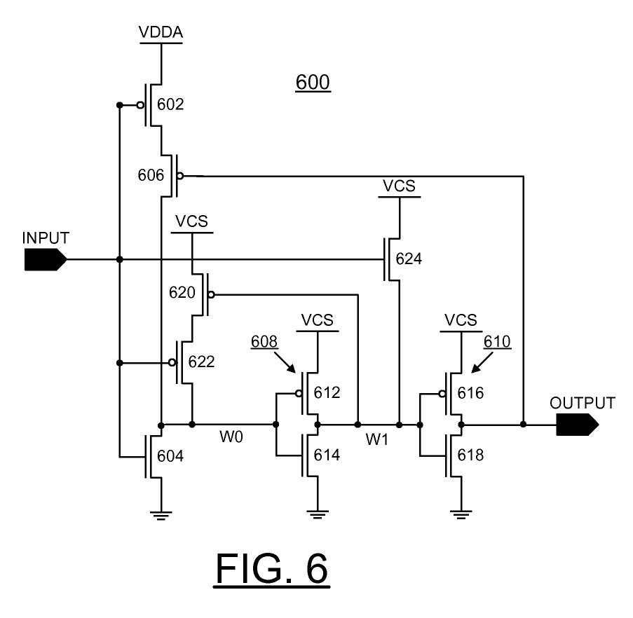

Referring to FIG. 6, there is shown an exemplary level shifter circuit generally designated by the reference character 600 in accordance with the preferred embodiment. Level shifter circuit 600 includes an input stage P-channel field effect transistor (PFET) 602 and an N-channel field effect transistor (NFET) 604 receiving an input signal INPUT. PFET 602 is connected between a first power supply voltage VDDA and a PFET 606 connected in series with the pull down NFET 604.

Level shifter circuit 600 includes an output stage pair of series connected inverters 608, 610 operating in a domain of a second power supply voltage VCS, the inverter 610 providing an output OUTPUT of level shifter circuit 600.

The series connected input stage path control PFET 606 has a gate connected to the output OUTPUT of level shifter circuit 600.

The pair of series connected inverters 608, 610 are defined by a series connected PFET 612 and NFET 614, and a series connected PFET 616 and NFET 618 respectively connected between the second power supply voltage VCS and ground. The drain source connection of PFET 606 and NFET 604 at node W0 is connected to an input of the first inverter 608 defined by a series connected PFET 612 and NFET 614.

A pair of series connected PFETs 620, 622 is connected between the second power supply voltage VCS and the input to the first inverter 608. The PFET 620 is a finisher PFET having a gate connected to a node W1 at an output of the first inverter and input to the second inverter 610 defined by PFET 616, NFET 618. The PFET 622 has a gate connected to the input signal INPUT.

Level shifter circuit 600 includes an additional NFET 624 connected between the second power supply voltage VCS and the output of the first inverter 608 and the input to the second inverter at node W1. The NFET 624 has a gate connected to the input signal INPUT. This NFET 624 pulls up the net W1 to power supply voltage VCS less the device threshold voltage VT of NFET 624, then PFET 612 pulls the net W1 up the rest of the way to the second power supply voltage VCS. Adding the NFET 624 in known 45-nanometer technology improves the overall delay by about 4.4% over the first embodiment of the invention of level shifter circuit 500 of FIG. 5.

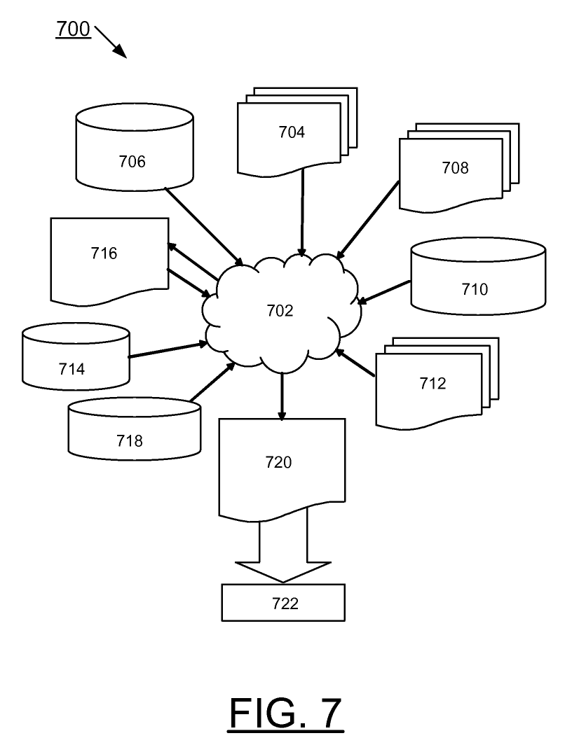

FIG. 7 shows a block diagram of an example design flow 700. Design flow 700 may vary depending on the type of IC being designed. For example, a design flow 700 for building an application specific IC (ASIC) may differ from a design flow 700 for designing a standard component. Design structure 702 is preferably an input to a design process 704 and may come from an IP provider, a core developer, or other design company or may be generated by the operator of the design flow, or from other sources. Design structure 702 comprises circuit 500, and circuit 600 in the form of schematics or HDL, a hardware-description language, for example, Verilog, VHDL, C, and the like. Design structure 702 may be contained on one or more machine readable medium. For example, design structure 702 may be a text file or a graphical representation of circuit 500. Design process 704 preferably synthesizes, or translates, circuit 500, and circuit 600 into a netlist 706, where netlist 706 is, for example, a list of wires, transistors, logic gates, control circuits, I/O, models, etc. that describes the connections to other elements and circuits in an integrated circuit design and recorded on at least one of machine readable medium. This may be an iterative process in which netlist 706 is resynthesized one or more times depending on design specifications and parameters for the circuit.

Design process 704 may include using a variety of inputs; for example, inputs from library elements 708 which may house a set of commonly used elements, circuits, and devices, including models, layouts, and symbolic representations, for a given manufacturing technology, such as different technology nodes, 32 nm, 45 nm, 90 nm, and the like, design specifications 710, characterization data 712, verification data 714, design rules 716, and test data files 718, which may include test patterns and other testing information. Design process 704 may further include, for example, standard circuit design processes such as timing analysis, verification, design rule checking, place and route operations, and the like. One of ordinary skill in the art of integrated circuit design can appreciate the extent of possible electronic design automation tools and applications used in design process 704 without deviating from the scope and spirit of the invention. The design structure of the invention is not limited to any specific design flow.

Design process 704 preferably translates an embodiment of the invention as shown in FIGS. 5, and 6 along with any additional integrated circuit design or data (if applicable), into a second design structure 720. Design structure 720 resides on a storage medium in a data format used for the exchange of layout data of integrated circuits, for example, information stored in a GDSII (GDS2), GL1, OASIS, or any other suitable format for storing such design structures.

Design structure 720 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as shown in FIGS. 5, and 6. Design structure 720 may then proceed to a stage 722 where, for example, design structure 720 proceeds to tape-out, is released to manufacturing, is released to a mask house, is sent to another design house, is sent back to the customer, and the like.

While the present invention has been described with reference to the details of the embodiments of the invention shown in the drawing, these details are not intended to limit the scope of the invention as claimed in the appended claims.

1. A low power level shifter circuit comprising:
an input inverter operating in a domain of a first voltage supply; said input inverter receiving an input signal and providing a first inverted signal output;
an output stage operating in a domain of a second voltage supply higher than the first voltage supply; said output stage including a first output inverter connected to said input inverter and a second output inverter connected in series with said first output inverter and providing a level shifted output signal having a voltage level corresponding to the second voltage supply; each of said first output inverter and said second output inverter being formed by a pair of transistors connected in series between the second voltage supply and ground and having a common gate input: and
a series connected finisher transistor and finisher control transistor connected between the second voltage supply and said common gate input to said first output inverter; said finisher control transistor being activated responsive to said input signal; and
a path control transistor controlling a path between the first voltage supply and the input inverter; said path control transistor being activated responsive to said level shifted output signal.

2. The low power level shifter circuit as recited in claim 1 wherein said series connected finisher transistor and finisher control transistor include a pair of series connected P-channel field effect transistors (PFETs).

3. The low power level shifter circuit as recited in claim 2 wherein said input signal is applied to a gate of said finisher control PFET.

4. The low power level shifter circuit as recited in claim 2 wherein said an output of said first output inverter is applied to a gate of said finisher PFET.

5. The low power level shifter circuit as recited in claim 2 wherein said finisher control PFET is turned off responsive to a one logic value of said input signal.

6. The low power level shifter circuit as recited in claim 5 wherein said finisher PFET is turned off responsive to said finisher control PFET being turned off.

7. The low power level shifter circuit as recited in claim 5 wherein said path control transistor is activated to maintain the path responsive to said level shifted output signal being a zero logic value with said one logic value of said input signal.

8. The low power level shifter circuit as recited in claim 1 wherein said path control transistor is a P-channel field effect transistor (PFET) and said level shifted output signal is applied to a gate of said path control PFET.

9. The low power level shifter circuit as recited in claim 1 further includes a pull up transistor connected between the second voltage supply and an output of said first output inverter.

10. The low power level shifter circuit as recited in claim 9 wherein said pull up transistor is an N-channel field effect transistor (NFET) and said input signal is applied to a gate of said pull up NFET.

11. A method for implementing voltage level shifters for integrated circuits comprising the steps of:
providing an input inverter operating in a domain of a first voltage supply; said input inverter receiving an input signal and providing a first inverted signal output;
connecting a first output inverter to said input inverter and connecting a second output inverter in series with said first output inverter for providing an output stage operating in a domain of a second voltage supply higher than the first voltage supply; and said output stage providing a level shifted output signal having a voltage level corresponding to the second voltage supply; each of said first output inverter and said second output inverter being formed by a pair of transistors connected in series between the second voltage supply and ground and having a common gate input; and
connecting a finisher transistor and a finisher control transistor in series between the second voltage supply and said common gate input to said first output inverter; and activating said finisher control transistor responsive to said input signal; and
connecting a path control transistor for controlling a path between the first voltage supply and the input inverter; and activating said path control transistor responsive to said level shifted output signal.

12. The method for implementing voltage level shifters for integrated circuits as recited in claim 11 further includes connecting a pull up transistor between the second voltage supply and an output of said first output inverter; and activating said pull up transistor responsive to said input signal.

13. The method for implementing voltage level shifters for integrated circuits as recited in claim 11 includes providing a pair of series connected P-channel field effect transistors (PFETs) for implementing said finisher transistor and said finisher control transistor and wherein activating said finisher control transistor responsive to said input signal includes applying said input signal to a gate of said finisher control PFET.

14. The method for implementing voltage level shifters for integrated circuits as recited in claim 13 includes applying an output of said first output inverter to a gate of said finisher PFET.

15. The method for implementing voltage level shifters for integrated circuits as recited in claim 13 wherein said finisher control PFET is turned off responsive to a one logic value of said input signal, and wherein said finisher PFET is turned off responsive to said finisher control PFET being turned off.

16. The method for implementing voltage level shifters for integrated circuits as recited in claim 11 includes providing is a P-channel field effect transistor (PFET) for implementing said path control transistor, and wherein activating said path control transistor responsive to said level shifted output signal includes applying said level shifted output signal to a gate of said path control PFET.

17. A design structure embodied in a machine readable medium used in a design process, the design structure comprising:
a low rower level shifter circuit tangibly embodied in the machine readable medium used in the design process, said low power level shifter circuit including an input inverter operating in a domain of a first voltage supply; said input inverter receiving an input signal and providing a first inverted signal output;
an output stage operating in a domain of a second voltage supply higher than the first voltage supply; said output stage including a first output inverter connected to said input inverter and a second output inverter connected in series with said first output inverter and providing a level shifted output signal having a voltage level corresponding to the second voltage supply; each of said first output inverter and said second output inverter being formed by a pair of transistors connected in series between the second voltage supply and ground and having a common gate input; and
a series connected finisher transistor and finisher control transistor connected between the second voltage supply and an input to said first output inverter; said finisher control transistor being activated responsive to said input signal; and
a path control transistor controlling a path between the first voltage supply and the input inverter; said path control transistor being activated responsive to said level shifted output signal, wherein the design structure, when read and used in the manufacture of a semiconductor chip produces a chip comprising the low rower level shifter circuit.

18. The design structure of claim 17, wherein the design structure comprises a netlist, which describes the low power level shifter circuit.

19. The design structure of claim 17, wherein the design structure resides on the machine readable medium as a data format used for the exchange of layout data of integrated circuits.

20. The design structure of claim 17, wherein the design structure includes at least one of test data files, characterization data, verification data, or design specifications.
